(19) United States
(12) Patent Application Publication
(10) Pub. No.: US 2026/0188389 A1
(43) Pub. Date: Jul. 2, 2026

(54) MEMORY DEVICE AND OPERATING METHOD OF THE MEMORY DEVICE

(71) Applicant: SK hynix Inc., Icheon-si Gyeonggi-do (KR)

(72) Inventor: Nam Cheol JEON, Icheon-si Gyeonggi-do (KR)

(73) Assignee: SK hynix Inc., Icheon-si Gyeonggi-do (KR)

(21) Appl. No.: 19/262,962

(22) Filed: Jul. 8, 2025

(30) Foreign Application Priority Data
Dec. 26, 2024 (KR) 10-2024-0197170

(51) Int. Cl. G11C 16/14; G11C 16/08; G11C 16/24

(52) U.S. Cl. CPC G11C 16/14; G11C 16/08; G11C 16/24

(57) ABSTRACT

A memory device includes a memory block including first sub-blocks and second sub-blocks between a source line and bit lines, a peripheral circuit configured to perform an erase operation of the memory block and pre-program operations of the first sub-blocks and then the second sub-blocks sequentially before the erase operation, and a control circuit configured to control the peripheral circuit, wherein each of the first and second sub-blocks includes first select transistors, memory cells, and second select transistors arranged between the source line and the bit lines, and wherein the control circuit is configured to control the peripheral circuit to apply a first pre-program voltage to word lines coupled to the memory cells during the pre-program operation of the first sub-blocks, and to apply a second pre-program voltage lower than the first pre-program voltage to the word lines during the pre-program operation of the second sub-blocks.

### CROSS-REFERENCE TO RELATED APPLICATION

The present application claims priority under 35 U.S.C. § 119(a) to Korean patent application number 10-2024-0197170 filed on Dec. 26, 2024, in the Korean Intellectual Property Office, the entire contents of which application is incorporated herein by reference.

### BACKGROUND

### 1. Technical Field

The present disclosure relates to a memory device and an operating method of the memory device, and more particularly, to a memory device configured to perform a pre-program operation performed before an erase operation and a method of operating the memory device.

### 2. Related Art

A memory device configured to store data may include a memory cell array, a peripheral circuit, and a control circuit. The memory cell array may include memory blocks, and the memory blocks may include memory cells in which data is stored. The peripheral circuit may program, read, or erase memory cells under the control of the control circuit. The control circuit may control the peripheral circuit to perform a program operation, a read operation, or an erase operation in response to a command.

A memory block may be implemented as a three-dimensional (3D) structure. In a memory block implemented as a 3D structure, memory cells are stacked in a direction perpendicular to a substrate. For example, in a memory block implemented as a 3D structure, memory cells may be stacked along a plug extending in a vertical direction from the substrate.

Due to the nature of manufacturing processes of a memory device, memory cells may have different sizes depending on the location of the memory cells. Memory cells of different sizes may have different electrical characteristics due to physical differences. For example, memory cells located closer to an outer edge of a memory block may have a larger size than memory cells located in a central region of the memory block, and upper memory cells in the stacked memory cells may be larger in size than lower memory cells.

Due to the size difference of the memory cells, the time taken for an erase operation and the time taken for a program operation, which are performed in the memory device, may be increased. For example, during an erase operation of a memory block, memory cells with relatively fast erase rates may be over-erased when memory cells with relatively slow erase rates are erased. The time taken for a subsequent program operation may be increased due to the over-erased memory cells.

### SUMMARY

According to an embodiment, a memory device may include: a memory block including first sub-blocks and second sub-blocks located between a source line and bit lines; a peripheral circuit configured to perform an erase operation of the memory block and pre-program operations of the first sub-blocks and then the second sub-blocks sequentially before the erase operation; and a control circuit configured to control the peripheral circuit. Each of the first and second sub-blocks includes first select transistors, memory cells, and second select transistors arranged between the source line and the bit lines. The control circuit is configured to control the peripheral circuit to apply a first pre-program voltage to word lines coupled to the memory cells during the pre-program operation of the first sub-blocks, and to apply a second pre-program voltage lower than the first pre-program voltage to the word lines during the pre-program operation of the second sub-blocks.

According to an embodiment, a method of operating a memory device includes: performing a first pre-program operation of first sub-blocks by applying a first pre-program voltage to word lines coupled to the first sub-blocks and second sub-blocks located between the first sub-blocks before an erase operation of a memory block including the first sub-blocks and the second sub-blocks; and performing, after the first pre-program operation of the first sub-blocks is performed, a second pre-program operation of the second sub-blocks by applying a second pre-program voltage lower than the first pre-program voltage to the word lines.

### BRIEF DESCRIPTION OF THE DRAWINGS

FIG. 1 is a diagram for describing a memory system;

FIG. 2 is a diagram for describing a memory device;

FIG. 3 is a diagram for describing a memory cell array;

FIG. 4 is a circuit diagram for describing a memory block;

FIG. 5 is a cross-sectional view for describing the structure of a string;

FIG. 6 is a plan view for describing the structure of a string;

FIG. 7 is a diagram for describing a memory block in which isolation regions are defined;

FIG. 8 is a cross-sectional view for describing a memory block including isolation patterns;

FIG. 9 is a diagram illustrating a method of operating a memory device according to an embodiment of the present disclosure;

FIG. 10 is a diagram for describing a threshold voltage distribution of memory cells according to an embodiment of the present disclosure;

FIGS. 11A and 11B are diagrams for describing a pre-program operation according to a first embodiment of the present disclosure;

FIG. 12 is a diagram for describing a pre-program operation according to a second embodiment of the present disclosure;

FIG. 13 is a diagram for describing a pre-program operation according to a third embodiment of the present disclosure;

FIG. 14 is a diagram for describing a pre-program operation according to a fourth embodiment of the present disclosure;

FIG. 15 is a diagram for describing a pre-program operation according to a fifth embodiment of the present disclosure;

FIG. 16 is a diagram for describing a pre-program operation according to a sixth embodiment of the present disclosure;

FIG. 17 is a diagram illustrating a memory card system to which a memory device according to an embodiment of the present disclosure is applied; and

FIG. 18 is a diagram illustrating a solid-state drive (SSD) system to which a memory device according to an embodiment of the present disclosure is applied.

### DETAILED DESCRIPTION

Specific structural or functional descriptions of examples of embodiments in accordance with concepts which are disclosed in this specification are illustrated only to describe embodiments in accordance with the concepts of the present disclosure. The examples of embodiments in accordance with the concepts may be carried out by various forms but the descriptions are not limited to the examples of embodiments described in this specification.

While terms such as “first” and “second” may be used to identify various components, such components should not be understood as being limited by the above terms. The above terminologies are used to distinguish one component from another component and are not intended to indicate a number or order of components.

According to some embodiments of the present disclosure, a memory device and an operating method of the memory device improves a threshold voltage distribution of memory cells during an erase operation to reduce the time required for a program operation.

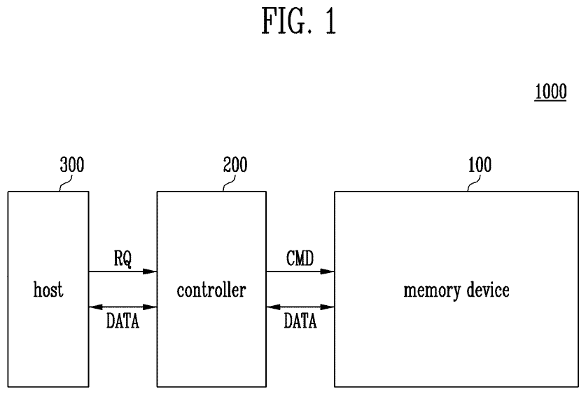

FIG. 1 is a diagram for describing a memory system 1000.

Referring to FIG. 1, the memory system 1000 may include a memory device 100, a controller 200, and a host 300.

The memory device 100 may store data. The memory device 100 may be a non-volatile memory device. A non-volatile memory device is a device in which stored data is retained even when supplied power is cut off.

The controller 200 may communicate between the host 300 and the memory device 100. The controller 200 may control the memory device 100 in accordance with a request RQ from the host 300. For example, upon receiving a request RQ for a program operation from the host 300, the controller 200 may generate a command CMD for the program operation and transfer the generated command CMD to the memory device 100. Upon receiving the request RQ for a read operation from the host 300, the controller 200 may generate the command CMD for the read operation and transfer the generated command CMD to the memory device 100. Upon receiving the request RQ for an erase operation from the host 300, the controller 200 may generate the command CMD for the erase operation and transfer the generated command CMD to the memory device 100.

The host 300 may communicate with the memory device 100 through the controller 200 using an interface protocol, such as Peripheral Component Interconnect-Express (PCI-E), Advanced Technology Attachment (ATA), Serial ATA (SATA), Parallel ATA (PATA), or Serial attached SCSI (SAS). Interface protocols are not limited to the above examples and may include various interfaces, such as Universal Serial Bus (USB), Multi-Media Card (MMC), Enhanced Small Disk Interface (ESDI), Integrated Drive Electronics (IDE), or the like.

The memory device 100 according to an embodiment may adjust a pre-program operation performed before an erase operation is performed to shorten the time taken for a program operation. For example, in a pre-program operation, the memory device may adjust a program voltage applied to word lines according to positions of strings included in a memory block. In addition to the program voltage, the memory device may adjust a voltage applied to at least one of a source line, a bit line, a drain select line, and a source select line.

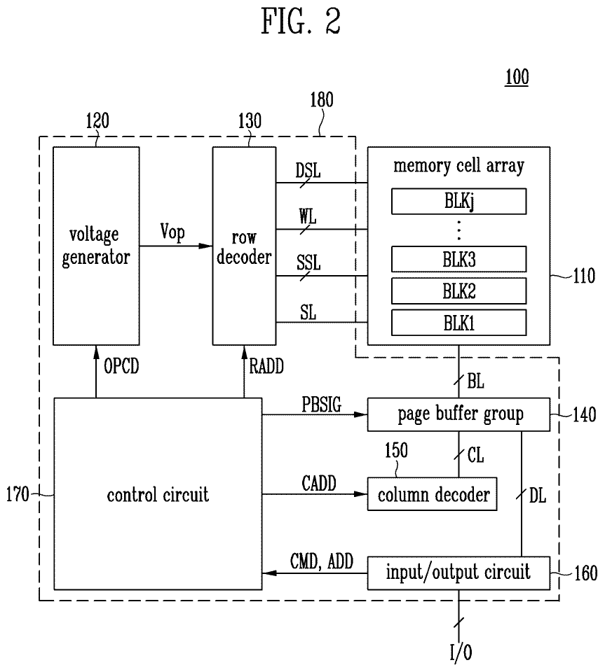

FIG. 2 is a diagram for describing a memory device.

Referring to FIG. 2, the memory device 100 may include a memory cell array 110 in which data is stored and a peripheral circuit 180 which performs a program, read, and erase operations.

The memory cell array 110 may include first to j-th memory blocks BLK1 to BLKj in which data is stored. Each of the first to j-th memory blocks BLK1 to BLKj includes a plurality of memory cells, and the memory cells may be implemented in a two-dimensional structure, in which the memory cells are arranged parallel to a substrate, or a three-dimensional structure, in which the memory cells are stacked in a direction perpendicular to the substrate. The first to j-th memory blocks BLK1 to BLKj according to the present embodiment may be implemented in a three-dimensional structure. Drain select lines DSL, word lines WL, and source select lines SSL may be coupled to each of the first to j-th memory blocks BLK1 to BLKj. A source line SL may be commonly coupled to the first to j-th memory blocks BLK1 to BLKj. The memory cell may store at least one bit of data according to a program method. For example, when a program operation is performed in a single-level cell (SLC) manner, one bit of data may be stored in one memory cell. When the program operation is performed in a multi-level cell (MLC) manner, two or more bits of data may be stored in one memory cell. For example, three bits of data may be stored in one memory cell when the program operation is performed in a triple-level cell (TLC) manner, and four bits of data may be stored in one memory cell in a quad-level cell (QLC) manner. In addition, data of five bits or more may be stored in one memory cell according to a program method.

The peripheral circuit 180 may include a voltage generator 120, a row decoder 130, a page buffer group 140, a column decoder 150, an input/output circuit 160, and a control circuit 170. In an embodiment, the control circuit 170 is separate from and not included in the peripheral circuit 180.

The voltage generator 120 may generate and output operating voltages Vop for various operations in response to an operating code OPCD. For example, the voltage generator 120 may generate and output a program voltage, a verify voltage, a read voltage, a pass voltage, an erase voltage, a turn-on voltage, a negative voltage, and the like. The voltage generator 120 may change a level of each of the operating voltages Vop in response to the operating code OPCD and may adjust the output time of each of the operating voltages Vop.

The row decoder 130 may select one of the first to j-th memory blocks BLK1 to BLKj included in the memory cell array 110 according to a row address RADD, and it may transfer the operating voltages Vop to the selected memory block.

The page buffer group 140 may be coupled to the memory cell array 110 via bit lines BL. For example, the page buffer group 140 may include page buffers (not shown) coupled to the bit lines BL. The page buffers may operate concurrently in response to page buffer control signals PBSIG and may temporarily store data during program or read operations. To this end, each of the page buffers may include a plurality of latches for temporarily storing data. The number of latches may vary depending on the program method.

The column decoder 150 may transfer data DATA between the input/output circuit 160 and the page buffer group 140 according to a column address CADD.

The input/output circuit 160 may be coupled to the controller 200 through input/output lines IO. The input/output circuit 160 may input/output the command CMD, an address ADD, and the data DATA through the input/output lines IO. For example, the input/output circuit 160 may transfer the command CMD and the address ADD received via the input/output lines IO to the control circuit 170, and it may transfer the data DATA received via the input/output lines IO to the column decoder 150. The input/output circuit 160 may output the data DATA received from the column decoder 150 to an external device through the input/output lines IO.

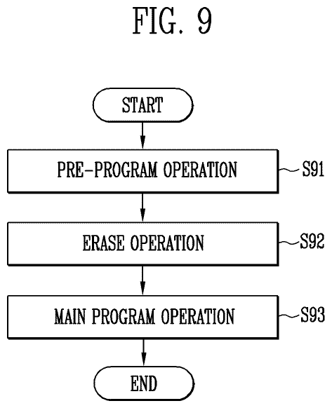

The control circuit 170 may output the operating code OPCD, the row address RADD, the page buffer control signals PBSIG, and the column address CADD in response to the command CMD and the address ADD. For example, the control circuit 170 may include software to execute a program, read, or erase operation in response to the command CMD and the addresses ADD, and the control circuit 170 may include hardware to output the operating code OPCD, the row address RADD, the page buffer control signal PBSIG, and the column address CADD under the control of the software. For different embodiments, the control circuit 170 may be configured with firmware that controls the control circuit 170 to perform the operations described herein with reference to FIGS. 9, 10, 11A, 11B, 12, 13, 14, 15, and 16.

The control circuit 170 may control the peripheral circuit 180 to initiate a pre-program operation of the selected memory block to be performed prior to an erase operation of the selected memory block. For example, the control circuit 170 may control the peripheral circuit 180 to perform pre-program operations of selected sub-blocks included in the selected memory block and a pre-program operation of unselected sub-blocks at different times. For example, during a pre-program operation of sub-blocks included in the selected memory block and located outside the selected memory block, the control circuit 170 may control the peripheral circuit 180 to apply a first pre-program voltage to word lines coupled to the selected memory block. During a pre-program operation of sub-blocks located in an inner region or a central region of the selected memory block among the sub-blocks included in the selected memory block, the control circuit 170 may control the peripheral circuit 180 to apply a second pre-program voltage lower than the first pre-program voltage to word lines coupled to the selected memory block. The control circuit 170 may modify the operating code OPCD such that a level of the pre-program voltage applied to the word lines WL may be adjusted according to the selected sub-blocks of the selected memory block. During the pre-program operation, the control circuit 170 may change the operating code OPCD such that the levels and times of voltages applied to the drain select lines, the source select lines, the bit lines, and the source line in addition to the pre-program voltage are adjusted.

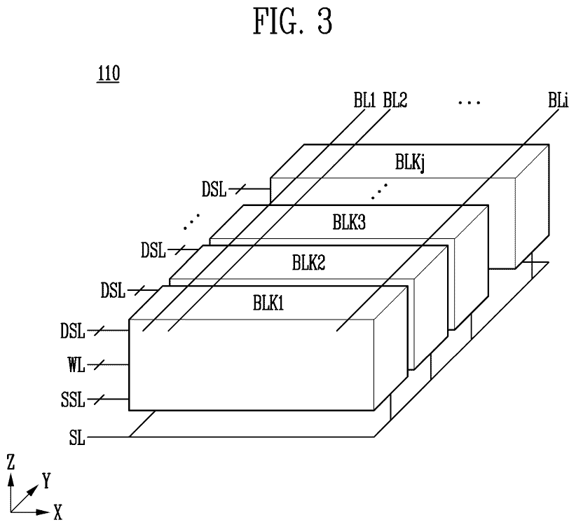

FIG. 3 is a diagram for describing the memory cell array 110.

Referring to FIG. 3, the memory cell array 110 may include the first to j-th memory blocks BLK1 to BLKj, where ‘j’ is a positive integer. The first to j-th memory blocks BLK1 to BLKj may be spaced apart from each other in a Y direction, and they may be located between the source line SL and first to i-th bit lines BL1 to BLi, where ‘i’ is a positive integer. The Drain select lines DSL, the word lines WL, and the source select lines SSL may be coupled to each of the first to j-th memory blocks BLK1 to BLKj. The operating voltages Vop shown in FIG. 2 may be applied through drain select lines DSL, the word lines WL, the source select lines SSL, the and source line SL coupled to a selected memory block among the first to j-th memory blocks BLK1 to BLKj, and the drain select lines DSL, the word lines WL, and the source select lines SSL coupled to the remaining unselected memory blocks may be floated. A pre-program operation according to this embodiment may be performed on a selected memory block among the first to j-th memory blocks BLK1 to BLKj.

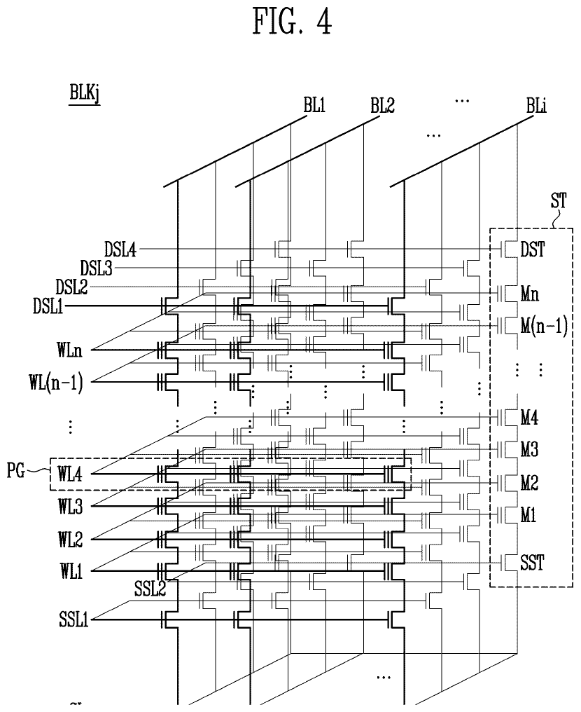

FIG. 4 is a circuit diagram for describing a memory block.

Referring to FIG. 4, the j-th memory block BLKj is shown by way of example, as the memory blocks may be configured identically to each other. The j-th memory block BLKj may include strings ST coupled between the source line SL and the first to i-th bit lines BL1 to BLi. The strings ST may be coupled in common to the source line SL. The first to i-th bit lines BL1 to BLi may be arranged spaced apart from each other in an X direction, and each of the first to i-th bit lines BL1 and BLi may extend in the Y direction. Strings arranged in the Y direction may be coupled in common to each of the first to i-th bit lines BL1 to BLi, and strings arranged in the X direction may be coupled to different first to i-th bit lines BL1 to BLi.

The numbers of source select transistors SST, first to n-th memory cells M1 to Mn, and drain select transistors DST included in each of the strings ST may vary depending on the memory device. For example, although FIG. 4 illustrates that each of the strings ST includes one source select transistor SST and one drain select transistor DST, each string ST may further include a plurality of source select transistors SST and drain select transistors DST arranged in the Z direction.

Gates of the source select transistors SST included in different strings ST may be coupled to the source select lines SSL, gates of the first to n-th memory cells M1 to Mn may be coupled to first to n-th word lines WL1 to WLn, and gates of drain select transistors DST may be coupled to the first to fourth drain select lines DSL1 to DSL4, where ‘n’ is a positive integer. The number of drain select lines may vary depending on the memory device, and thus, is not limited to the number shown in FIG. 4.

The source select lines SSL may be commonly coupled to the source select transistors SST arranged in the X and Y directions. However, some source select lines SSL arranged in the Y direction may be spaced apart from each other. Each of the first to n-th word lines WL1 to WLn may be commonly coupled to memory cells arranged in the X and Y directions. For example, the n-th memory cells Mn arranged in the X and Y directions may be commonly coupled to the n-th word lines WLn, and the n-th word lines WLn may be coupled to each other. For example, (n−1)-th memory cells M(n−1) arranged in the X and Y directions may be commonly coupled to (n−1)-th word lines WL(n−1), and the (n−1)-th word lines WL(n−1) may be coupled to each other. The n-th word line WLn and the (n−1)-th word line WL(n−1) are spaced apart from each other. The group of memory cells commonly coupled to one of the first to n-th word lines WL1 to WLn is a page PG. For example, fourth memory cells M4 commonly coupled to a fourth word line WL4 are grouped into one page PG. Program operations and read operations may be performed on a page (PG) basis. When the fourth word line WL4 is a selected word line, the remaining word lines are unselected word lines.

The first to fourth drain select lines DSL1 to DSL4 are spaced apart from each other. Each of the first to fourth drain select lines DSL1 to DSL4 may be commonly coupled to the drain select transistors DST arranged in the X direction. Thus, during a program or read operation, memory cells included in the strings ST coupled to a selected drain select line among the first to fourth drain select lines DSL1 to DSL4 may be selected.

A voltage supplied to the source line SL may be applied to channels of the strings ST when source select transistors SST are turned on, and the source line SL and the strings ST may be electrically cut off when the source select transistors SST are turned off. The source select transistors SST may be turned on when a turn-on voltage is applied to the first or second source select line SSL1 or SSL2, and they may be turned off when a turn-off voltage is applied. For example, when the turn-on voltage is applied to the first source select line SSL1 and the turn-off voltage is applied to the second source select line SSR2, source select transistors coupled to the first source select line SSL1 are turned on, and the source select transistors SST coupled to the second source select line SSR2 are turned off. The turn-on voltage may be a positive voltage higher than 0 V, and the turn-off voltage may be a ground voltage or a negative voltage lower than 0 V.

A voltage supplied to the first to i-th bit lines BL1 to BLi may be applied to channels of the strings ST when the drain select transistors DST are turned on, and the first to i-th bit lines BL1 to BLi and the strings ST may be electrically cut off when the drain select transistors DST are turned off. Referring to the drain select transistors DST coupled to the first drain select line DSL1 as an example, the drain select transistor DST may be turned on when the turn-on voltage is applied to the first drain select line DSL1, and it may be turned off when the turn-off voltage is applied. The turn-on voltage applied to the first drain select line DSL1 may also be a positive voltage higher than 0 V, and the turn-off voltage may also be a ground voltage or a negative voltage lower than 0 V.

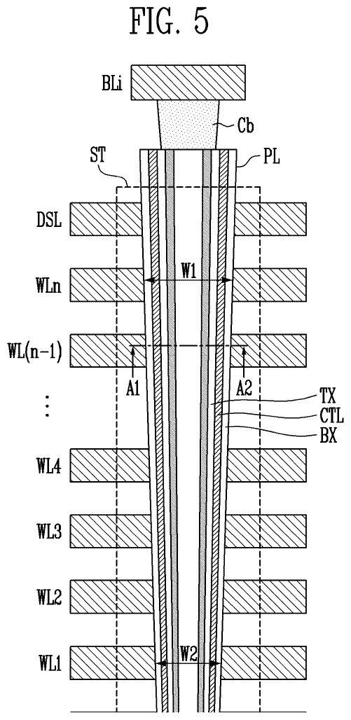

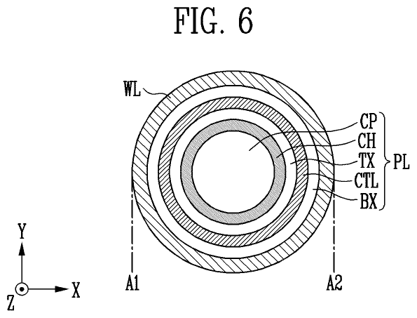

FIG. 5 is a cross-sectional view for describing the structure of a string ST, and FIG. 6 is a plan view for describing the structure of the string ST.

Referring to FIGS. 5 and 6, the string ST may include a plug PL penetrating through the source select line SSL, the first to n-th word lines WL1 to WLn, and the drain select line DSL stacked at a distance from each other. The source select line SSL, the first to n-th word lines WL1 to WLn, and the drain select line DSL may include a metal material, such as tungsten (W), molybdenum (Mo), cobalt (Co), nickel (Ni), or the like, or may include a semiconductor material, such as silicon (Si) or polysilicon (Poly-Si), but is not limited thereto. The plug PL may extend in a Z direction between the source line SL and the i-th bit line BLi. A bit line contact Cb may be located between the plug PL and the i-th bit line BLi.

The plug PL may include a core pillar CP, a channel layer CH, a tunnel isolation layer TX, a charge trap layer CTL, and a blocking layer BX. The core pillar CP may be in the form of a cylinder, a square pillar, or a polygonal pillar, and may include an insulating material or a conductive material. The channel layer CH may surround the core pillar CP and include polysilicon. The tunnel isolation layer TX may surround the channel layer CH and include an oxide layer. The charge trap layer CTL may surround the tunnel isolation layer TX and include a nitride film. The blocking layer BX may surround the charge trap layer CTL and include an oxide layer. A lower part of the channel layer CH may be in contact with the source line SL, and an upper part of the channel layer CH may be in contact with the bit line contact Cb. The bit line contact Cb may be located between the i-th bit line BLi and the plug PL.

The plug PL extending in the Z direction may have a varying width depending on the height due to the characteristics of the manufacturing processes. Specifically, the plug PL may increase in width with an increase of height in the Z direction. In other words, the width of the plug PL may narrower from the top to the bottom of the plug PL. For example, when the first word line WL1 is located lowest and the n-th word line WLn is located highest among the first to n-th word lines WL1 to WLn coupled to the string ST, assuming that a portion of the plug PL which is in contact with the n-th word line WLn has a first width W1, a portion of the plug PL which is in contact with the first word line WL1 may have a second width W2 which is less than the first width W1.

FIG. 6 shows a planar structure of the plug PL taken along the A1-A2 direction.

Referring to FIG. 6, the plug PL may include the core pillar CP, the channel layer CH, the tunnel isolation layer TX, the charge trap layer CTL, and the blocking layer BX. The channel layer CH may surround the core pillar CP. The tunnel isolation layer TX may surround the channel layer CH. The charge trap layer CTL may surround the tunnel isolation layer TX. The blocking layer BX may surround the charge trapping layer CTL. A word line WL may surround the blocking layer BX.

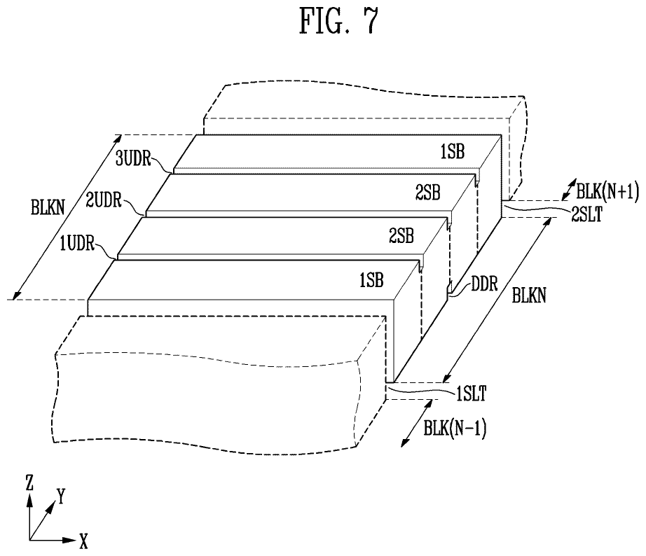

FIG. 7 is a diagram for describing a memory block in which isolation regions are defined.

Referring to FIG. 7, an (N−1)-th memory block BLK(N−1), an N-th memory block BLKN, and an (N+1)-th memory block BLK(N+1), where ‘N’ is a positive integer, may be spaced apart from each other in the Y direction. The (N−1)-th memory block BLK(N−1), the N-th memory block BLKN, and the (N+1)-th memory block BLK(N+1) may be spaced apart from each other by a first slit 1SLT and a second slit 2SLT. For example, the (N−1)-th memory block BLK(N-1) and the N-th memory block BLKN may be spaced apart from each other by the first slit 1SLT, and the N-th memory block BLKN and the (N+1)-th memory block BLK(N+1) may be spaced apart from each other by the second slit 2SLT. The (N−1)-th memory block BLK(N−1), the N-th memory block BLKN, and the (N+1)-th memory block BLK(N+1) may be configured to be identical to each other, so the N-th memory block BLKN will be described below as a representative example.

In the N-th memory block BLKN, first to third upper isolation regions 1UDR to 3UDR and a lower isolation region DDR may be defined. Each of the first to third upper isolation regions 1UDR to 3UDR extends in the X direction on top of the N-th memory block BLKN. The drain select lines included in the N-th memory block BLKN are separated by the first to third upper isolation regions 1UDR to 3UDR. The lower isolation region DDR of the N-th memory block BLKN also extends in the X direction. Source select lines included in the N-th memory block BLKN are separated by the lower isolation region DDR. For example, the N-th memory block BLKN may include a plurality of sub-blocks 1SB and 2SB which are divided by the first to third upper isolation regions 1UDR to 3UDR. The first sub-blocks 1SB may be located on the outer edges of the N-th memory block BLKN, and the second sub-blocks 2SB may be positioned in the middle of the N-th memory block BLKN between the first sub-blocks 1SB. For example, one of the first sub-blocks 1SB may be adjacent to the first slit 1SLT, and another first sub-block 1SB may be adjacent to the second slit 2SLT. Thus, the second sub-blocks 2SB may be located between the first sub-blocks 1SB. Although strings included in each of the first and second sub-blocks 1SB and 2SB are of substantially the same size, the strings may have different sizes depending on their location due to limitations in the manufacturing processes of the memory device. For example, the size of the strings included in the first sub-blocks 1SB may be larger than the size of the strings included in the second sub-blocks 2SB. When the sizes of the strings are different, the sizes of the memory cells may also be different. When the memory cells have different sizes, the memory cells may be programmed or erased at different speeds even if the same voltage is applied to the memory cells. When the memory cells are programmed or erased at different speeds, the time required for a program operation or an erase operation may be increased, and a distribution of threshold voltages of the memory cells may be widened. Therefore, an embodiment of the present disclosure provides a technique of preventing or mitigating degradation of the threshold voltage distribution due to the size difference of the memory cells, thereby reducing the time required for a program operation.

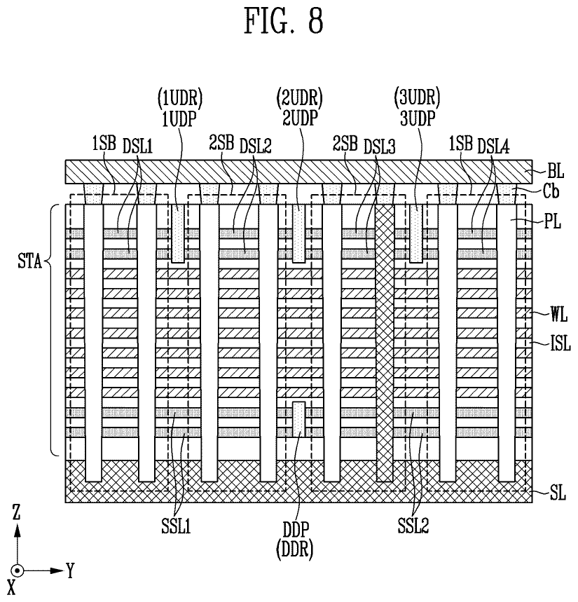

FIG. 8 is a cross-sectional view for describing a memory block including isolation patterns, and shows a cross section obtained by cutting the N-th memory block BLKN illustrated in FIG. 7 into a YZ plane.

Referring to FIG. 8, the memory block may include a stacked structure STA located between the source line SL and the bit line BL, and it may include the plugs PL located in the stacked structure STA. The bit line contacts Cb may be located between the stack structure STA and the bit line BL. The plugs PL may extend to the bottom or top of the stack structure STA, or they may extend to the bottom and top of the stack structure STA. The bottom of the plugs PL may abut or extend into the source line SL and the top of the plugs PL may abut the bit line contacts Cb. The plugs PL may abut the bit line contacts Cb, respectively, and the bit line contacts Cb may abut the bit line BL in common. The plugs PL may include memory cells, and the structure of each of the plugs PL is described with reference to FIG. 6. Plugs PL containing memory cells may be located in the stacked structure STA. The plugs PL may extend in the Z direction.

The stacked structure STA may include interlayer insulating layers ISL, first and second source select lines SSL1, SSL2, word lines WL, and first to fourth drain select lines DSL1 to DSL4. The interlayer insulating layers ISL may include a silicon oxide layer. The first and second source select lines SSL1 and SSL2, the word lines WL, and the first to fourth drain select lines DSL1 to DSL4 may include the same conductive film as each other. For example, the first and second source select lines SSL1 and SSL2, the word lines WL, and the first to fourth drain select lines DSL1 to DSL4 may include a metal material, such as tungsten (W), molybdenum (Mo), cobalt (Co), and nickel (Ni), or a semiconductor material, such as silicon (Si) or polysilicon (Poly-Si).

The first and second source select lines SSL1 and SSL2 may be separated from each other by a lower isolation pattern DDP. The lower isolation pattern DDP is an insulating pattern formed in the lower separation region (DDR in FIG. 7). The first source select lines SSL1 may be stacked with each other, and the second source select lines SSR2 may be stacked with one another. The stacking number of first source select lines SSL1 and the second source select lines SSR2 may vary depending on the memory device. The word lines WL may be located over the first and second source select lines SSL1, SSL2. Each of the word lines WL extends in the XY plane and is spaced apart from the other word lines WL in the Z direction. The first to fourth drain select lines DSL1 to DSL4 may be separated from each other by the first to third upper isolation patterns 1UDP to 3UDP. The first to third upper isolation patterns 1UDP to 3UDP are insulation patterns formed in the first to third upper isolation regions 1UDR to 3UDR shown in FIG. 7. For example, the first upper isolation pattern 1UDP is an insulation pattern formed in the first upper isolation region 1UDR shown in FIG. 7, the second upper isolation pattern 2UDP is an insulating pattern formed in the second upper isolation region 2UDR shown in FIG. 7, and the third upper isolation pattern 3UDP is an isolation pattern formed in the third upper isolation region 3UDR shown in FIG. 7. The first upper isolation pattern 1UDP separates the first drain select lines DSL1 and the second drain select lines DSL2 from each other, the second upper isolation pattern 2UDP separates the second drain select lines DSL2 and the third drain select lines DSL3 from each other, and the third upper isolation pattern 3UDP separates the third drain select lines DSL3 and the fourth drain select lines DSL4 from each other.

The first drain select lines DSL1 may be stacked with one another, the second drain select lines DSL2 may be stacked with one another, the third drain select lines DSL3 may be stacked with one another, and the fourth drain select lines DSL4 may be stacked with one another. The number of stacked first to fourth drain select lines DSL1 to DSL4 may vary depending on the memory device.

The first and second sub-blocks 1SB and 2SB may be distinguished by the first to third upper isolation patterns 1UDP to 3UDP. Thus, the plugs PL coupled to the first drain select lines DSL1 are included in a first sub-block 1SB, the plugs PL coupled to the second drain select lines DSL2 are included in a second sub-block 2SB, the plugs PL coupled to a third drain select lines DLS3 are included in a second sub-block 2SB, and the plugs PL coupled to the fourth drain select lines DSL4 are included in a first sub-block 1SB.

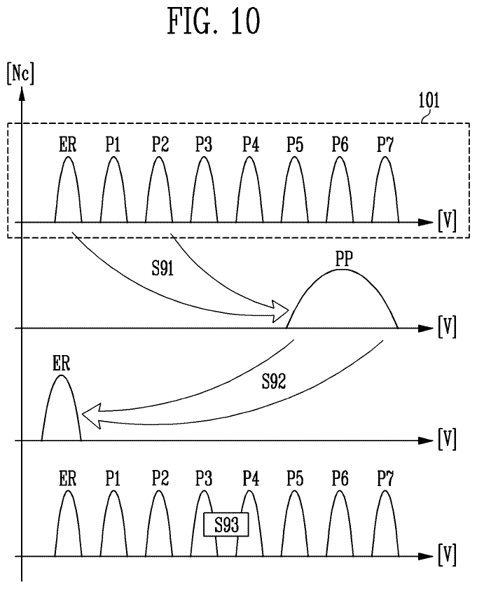

FIG. 9 is a diagram illustrating a method of operating a memory device according to an embodiment of the present disclosure, and FIG. 10 is a diagram illustrating threshold voltage distributions of memory cells according to an embodiment.

Referring to FIGS. 9 and 10, an erase operation of a memory block is an operation of lowering a threshold voltage distribution of memory cells to an erase state. Thus, the memory block selected for the erase operation may be the memory block for which the main program operation has already been performed (101). When a main program operation is performed in a multi-level cell (MLC) manner rather than a single-level cell (SLC) manner, the programmed memory cells may have two or more threshold voltage distributions. In an embodiment to be described below, the main program operation is performed in a triple-level cell (TLC) manner, but the present teachings are not limited to the triple-level cell (TLC) manner. When a program operation is performed in the triple-level cell (TLC) manner, the memory cells may be in an erase state ER or in one of the first to seventh program states P1 to P7 (101).

Before an erase operation is performed on a previously programmed (101) memory block, a pre-program operation is performed (S91). The pre-program operation may be performed to reduce a threshold voltage difference of memory cells included in the selected memory block. The memory cells included in the selected memory block may be programmed with various threshold voltage distributions (ER or P1 to P7). Therefore, threshold voltages of memory cells which are relatively low may be increased through the pre-program operation. The memory cells on which the pre-program operation has been performed may have a threshold voltage distribution corresponding to a pre-program state PP. That is, the memory cells included in the selected memory block may be pre-programmed to be in the pre-program state PP. As such, the pre-program operation to increase the threshold voltages of memory cells which are relatively low may be performed by applying a pre-program voltage to all word lines coupled to the selected memory block. Alternatively, the pre-program operation may be performed by applying a pre-program voltage to the word lines coupled to the selected memory block at different times. A method of applying a pre-program voltage to all word lines coupled to a selected memory block is described below.

A pre-program operation may be performed without a verify operation. For example, the pre-program operation may be performed by applying at least one pre-program pulse to all word lines coupled to the selected memory block. A level of the pre-program voltage used for the pre-program operation may be set between an average level and a maximum level of program voltages used in a main program operation.

A pre-program operation according to an embodiment may be performed at different times in units of sub-blocks included in the selected memory block to mitigate or prevent degradation of pre-program performance according to the locations of the memory cells included in the memory block. Pre-program performance degradation means that threshold voltage variations occur depending on the locations of the memory cells. For example, among the sub-blocks included in the selected memory block, a pre-program speed of first sub-blocks adjacent to slits may be slower than a pre-program speed of second sub-blocks located between the first sub-blocks. Therefore, the pre-program operation may reduce a difference in pre-program speeds of sub-blocks whose pre-program speeds may be different from each other.

For example, among the sub-blocks included in the selected memory block, the first sub-blocks adjacent to the slits and the second sub-blocks located between the first sub-blocks may be pre-programmed at different times. For example, when the first sub-blocks are selected sub-blocks, then the second sub-blocks are unselected sub-blocks. When the second sub-blocks are selected sub-blocks, then the first sub-blocks are unselected sub-blocks. After a pre-program operation of the selected sub-blocks is completed, a pre-program operation of the unselected sub-blocks may be performed. That is, when the pre-program operation of the selected sub-blocks is completed, the unselected sub-block are designated as a selected sub-blocks, and a pre-program operation of the newly designated selected sub-blocks may be subsequently performed. In a pre-program operation according to an embodiment, levels of pre-program voltages may be adjusted according to respective sub-blocks. When a pre-program operation is performed on a sub-block whose pre-program speed is relatively fast, a level of the pre-program voltage applied to word lines may be set to be lower than a reference level. For example, when a level of a pre-program voltage applied during a pre-program operation of the first sub-blocks is set to the reference level, a level of a pre-program voltage applied during a program operation of the second sub-blocks may be set to be lower than the reference level and higher than 0 V.

In addition, in a pre-program operation according to an embodiment, a voltage applied to at least one of the bit lines and the source line may be changed. For example, in a pre-program operation, the voltage applied to the bit lines may be lower than a reference bit line voltage, thereby increasing threshold voltages of memory cells included in the selected memory block which are located closer to the bit lines than the source line. During the pre-program operation, the voltage applied to the source line may be higher than a reference source line voltage, thereby lowering threshold voltages of memory cells included in the selected memory block which are located closer to the source line than the bit lines.

Alternatively, the voltage applied to the bit lines may be increased before the pre-program voltage is applied to the word lines, to quickly improve a pre-program speed of memory cells located relatively at a relatively upper part of the selected memory block. Alternatively, the voltage applied to the source lines may be increased before the pre-program voltage is applied to the word lines, or it may be increased and then decreased again, to improve a pre-program speed of memory cells located at a relatively lower part of the selected memory block.

According to the above-described embodiments, the memory cells included in a selected memory block are in the pre-program state PP, and the width of a threshold voltage distribution corresponding to the pre-program state PP may be narrower than for the previous program state shown at 101 in FIG. 10.

When the pre-program operation (S91) of the selected memory block is completed, an erase operation of the selected memory block is performed (S92). The erase operation may be performed concurrently on the sub-blocks included in the selected memory block. The erase operation may be performed in a gate-induced drain leakage (GIDL) manner. When an erase voltage is applied to the bit lines, the GIDL may occur in the region where the drain select transistors are located. When an erase voltage is applied to the source line, the GIDL may occur in the region where the source select transistors are located. When an erase voltage is applied to the bit lines and the source line, the GIDL may occur in the region where the drain select transistors and the source select transistors are located. When an erase operation is performed on the selected memory block, memory cells in the pre-program state PP are changed to the erase state ER. Because the threshold voltage distribution of the memory cells pre-programmed in the pre-program operation S91 is narrower than the distribution shown at 101, a speed at which the memory cells are erased to the erase state ER may be faster as compared to omitting the pre-program operation S91, and the width of the threshold voltage distribution corresponding to the erase state ER may be narrower as compared to omitting the pre-program operation S91.

When a program command is input to the memory device after the erase operation (S92) is completed, the memory device may perform a main program operation of the selected memory block (S93). When the main program operation is performed in a triple-level cell (TLC) manner, the memory cells may be programmed to the erase state ER or one of the first to seventh program states P1 to P7. Because the width of the threshold voltage distribution of the memory cells erased in step S92 is narrower as compared to otherwise omitting step S91, the speed of the main program operation performed in step S93 may be increased. That is, because the number of memory cells which have been over-erased in step S92 may decrease, the time taken for the main program operation in step S93 may be shortened.

Various embodiments of the pre-program operation performed in step S91 as described above will be described in detail below.

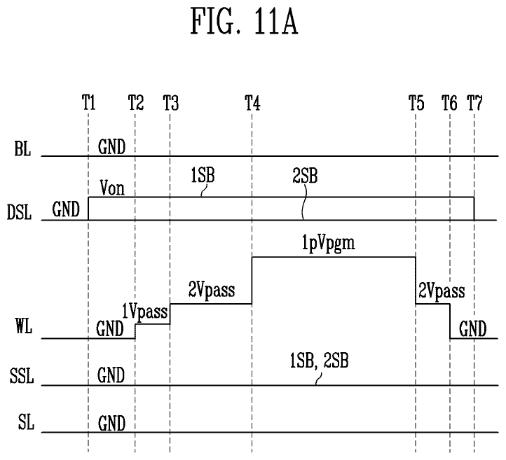

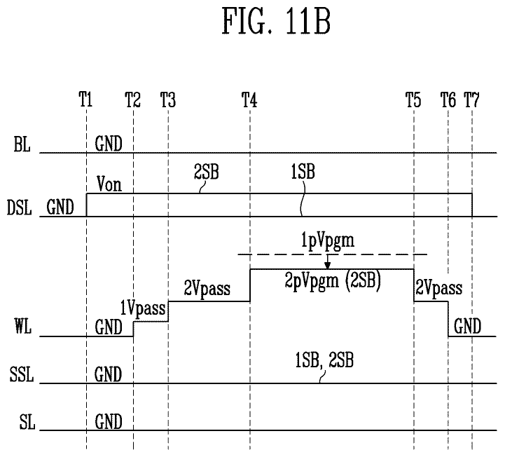

FIGS. 11A and 11B are diagrams for describing a pre-program operation according to a first embodiment of the present disclosure.

Referring to FIGS. 11A and 11B, the pre-program operation according to the first embodiment may be performed on the first sub-blocks 1SB and the second sub-blocks 2SB included in the selected memory block, sequentially. The first and second sub-blocks 1SB and 2SB may be the first and second sub-blocks 1SB and 2SB as shown in FIGS. 7 and 8. For example, the first sub-blocks 1SB may be located at both ends of the selected memory block, and the second sub-blocks 2SB may be located between the first sub-blocks 1SB. The pre-program operation may be performed on the second sub-blocks 2SB after being performed on the first sub-blocks 1SB, or it may be performed on the first sub-blocks 1SB after being performed on the second sub-block 2SB.

FIG. 11A is a diagram for describing a pre-program operation performed on the first sub-blocks 1SB, and FIG. 11B is a diagram for describing a pre-program operation performed on the second sub-blocks 2SB.

Referring to FIG. 11A, at a first time T1 when a pre-program operation starts, a turn-on voltage Von may be applied to the drain select lines DSL coupled to the first sub-blocks 1SB, and a ground voltage GND may be applied to the drain select lines DSL coupled to the second sub-blocks 2SB. That is, assuming that the first sub-blocks 1SB are selected sub-blocks and the second sub-blocks 2SB are unselected sub-blocks, a turn-on voltage Von may be applied to the drain select lines DSL coupled to the selected sub-block, and the ground voltage GND may be applied to the drain select lines DSL coupled to unselected sub-blocks. The turn-on voltage Von applied to the drain select lines DSL coupled to the first sub-blocks 1SB may be set to a positive voltage for turning on the drain select transistors. The ground voltage GND applied to the drain select lines DSL coupled to the second sub-blocks 2SB is a voltage for turning off the drain select transistors included in the second sub-blocks 2SB. The ground voltage GND may be applied to the source select lines SSL coupled to the first and second sub-blocks 1SB and 2SB.

The ground voltage GND may be applied to the bit lines BL. Because the drain select transistors of the first sub-blocks 1SB are turned on and the source select transistors thereof are turned off, channels of plugs included in the first sub-block 1SB may be electrically coupled to the bit lines BL. Thus, the potentials of the channels of the first select blocks 1SB may be lowered to a ground voltage GND level. Because the drain select transistors and the source select transistors of the second sub-blocks 2SB are turned off, channels of plugs included in the second sub-block 2SB are in a floating state.

The ground voltage GND may be applied to the source line SL. At the first time T1, the ground voltage GND may be applied to the word lines WL.

At a second time T2, a first pass voltage 1Vpass higher than the ground voltage GND may be applied to the word lines WL. The first pass voltage 1Vpass may be applied to all word lines WL to turn on all memory cells included in the selected memory block.

At a third time T3, a second pass voltage 2Vpass which is higher than the first pass voltage 1Vpass may be applied to the word lines WL. The second pass voltage 2Vpass may be applied to the word lines WL to gradually increase the potentials of the word lines WL before a first pre-program voltage 1pVpgm is applied to the word line WL. For some embodiments, gradually increasing or decreasing a potential means that the potential transitions from a first potential to a second potential through an intermediary potential having a level between the first and second potentials. For example, the potential of the word lines WL may gradually transition from the first pass voltage 1Vpass up to the first pre-program voltage 1pVpgm through the second pass voltage 2Vpass. The potential of the word lines WL may also gradually transition from the first pre-program voltage 1pVpgm down to the ground voltage GND through the second pass voltage 2Vpass.

At a fourth time T4, the first pre-program voltage 1pVpgm may be applied to the word lines WL. Because the potentials of the channels of the first sub-blocks 1SB have a level of the ground voltage GND, the threshold voltages of the memory cells included in the first sub-blocks 1SB may be increased. Because the channels of the second sub-blocks 2SB are in a floating state, the channels thereof may be boosted due to the potentials of the word lines WL. Thus, the memory cells included in the second sub-blocks 2SB may remain erased. The threshold voltages of the memory cells included in the first sub-blocks 1SB may increase from the fourth time T4 to a fifth time T5.

At the fifth time T5, the potentials of the word lines WL may be lowered gradually. For example, the second pass voltage 2Vpass lower than the first pre-program voltage 1pVpgm may be applied to the word lines WL. Though not shown in FIG. 11A, the potentials of the word lines WL may be lowered gradually or stepwise between the fifth time T5 and a sixth time T6.

At the sixth time T6, the word lines WL may be discharged. For example, the ground voltage GND may be applied to the word lines WL.

At a seventh time T7, the drain select lines DSL coupled to the first sub-blocks 1SB may be discharged.

Referring to FIG. 11B, a pre-program operation of the second sub-blocks 2SB may be performed similarly to the pre-program operation of the first sub-blocks 1SB as described with reference to FIG. 11A. However, in the pre-program operation of the second sub-blocks 2SB, a second pre-program voltage 2pVpgm lower than the first pre-program voltage 1pVpgm is applied to the word lines WL. That is, because a pre-program speed of the second sub-blocks 2SB included in the selected memory block may be faster than a pre-program speed of the first sub-blocks 1SB, the level of the pre-pre-program voltage applied to the word lines WL may be adjusted differently according to each sub-block to similarly match the pre-pre-program speeds of the first and second sub-block 1SB and 2SB. The remaining intervals except for the second pre-program voltage 2pVpgm applied to the word lines WL between the fourth time T4 and the fifth time T5 are the same as in the pre-program operation performed in the first sub-blocks 1SB, and thus, a redundant description thereof is omitted.

The pre-program operation may be performed on the second sub-blocks 2SB after being performed on the first sub-blocks 1SB, or it may be performed on the first sub-blocks 1SB after being performed on the second sub-blocks 2SB.

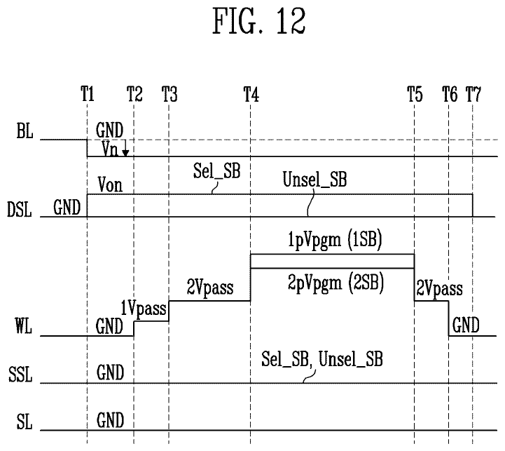

FIG. 12 is a diagram for describing a pre-program operation according to a second embodiment of the present disclosure.

Referring to FIG. 12, at the first time T1, when the pre-program operation starts, the turn-on voltage Von may be applied to the drain select lines DSL coupled to selected sub-blocks Sel_SB, and the ground voltage GND may be applied to the drain select lines DSL coupled to unselected sub-blocks Unsel_SB. When the selected sub-blocks Sel_SB are the first sub-blocks 1SB shown in FIGS. 7 and 8, the unselected sub-blocks Unsel_SB are the second sub-blocks 2SB shown in FIGS. 7 and 8. When the selected sub-blocks Sel_SB are the second sub-blocks 2SB, the unselected sub-blocks Unsel_SB are the first sub-blocks 1SB.

The turn-on voltage Von may be applied to the drain select lines DSL coupled to the selected sub-blocks Sel_SB, and the ground voltage GND may be applied to the drain select lines DSL coupled to the unselected sub-blocks Unsel_SB. The turn-on voltage Von applied to the drain select lines DSL coupled to the selected sub-blocks Sel_SB may be set to a positive voltage for turning on the drain select transistors. The ground voltage GND applied to the drain select lines DSL coupled to the unselected sub-blocks Unsel_SB is a voltage for turning off the drain select transistors included in the unselected sub-blocks Unsel_SB. The ground voltage GND may be applied to the source select lines SSL coupled to the selected sub-blocks Sel_SB and the unselected sub-blocks Unsel_SB.

A negative voltage Vn lower than the ground voltage GND may be applied to the bit lines BL. As the potentials of the bit lines BL decrease, the threshold voltages of the memory cells included in the selected sub-blocks Sel_SB may increase more rapidly, so that the time taken for the pre-program operation may be shortened. Because the drain select transistors of the selected sub-blocks Sel_SB are turned on and the source select transistors are turned off, the channels of the plugs included in the selected sub-blocks Sel_SB may be electrically coupled to the bit lines BL. Thus, the potentials of the channels of the selected sub-blocks Sel_SB may be lowered to the negative voltage Vn level. Because the drain select transistors and the source select transistors of the unselected sub-blocks Unsel_SB are turned off, the channels of the plugs included in the unselected sub-blocks Unsel_SB are in a floating state.

The ground voltage GND may be applied to the source line SL. At the first time T1, the ground voltage GND may be applied to the word lines WL.

At the second time T2, the first pass voltage 1Vpass higher than the ground voltage GND may be applied to the word lines WL. The first pass voltage 1Vpass may be applied to all word lines WL to turn on all memory cells included in the selected memory block.

At the third time T3, the second pass voltage 2Vpass which is higher than the first pass voltage 1Vpass may be applied to the word lines WL. The second pass voltage 2Vpass may be applied to the word lines WL to gradually increase the potentials of the word lines WL before the first or second pre-program voltage 1pVpgm or 2pVpgm is applied to the word lines WL.

At the fourth time T4, the first or second pre-program voltage 1pVpgm or 2pVpgm may be applied to the word lines WL. For example, when the first sub-blocks 1SB are the selected sub-blocks Sel_SB, the first pre-program voltage 1pVpgm may be applied to the word lines WL. When the second sub-blocks 2SB are the selected sub-blocks Sel_SB, the second pre-program voltage 2pVpgm may be applied to the word lines WL.

Because the potentials of the channels of the selected sub-blocks Sel_SB have the negative voltage Vn level, the threshold voltages of the memory cells included in the selected sub-blocks Sel_SB may be increased by the first or second pre-program voltage 1pVpgm or 2pVpgm. Because the channels of the unselected sub-blocks Unsel_SB are in a floating state, the channels thereof may be boosted due to the potentials of the word lines WL. Thus, the memory cells included in the unselected sub-blocks Unsel_SB may remain erased. The threshold voltages of the memory cells included in the first sub-blocks 1SB may increase from the fourth time T4 to the fifth time T5.

At the fifth time T5, the potentials of the word lines WL may be lowered gradually. For example, the second pass voltage 2Vpass, which is lower than the first or second pre-program voltage 1pVpgm or 2pVpgm, may be applied to the word lines WL. Though not shown in FIG. 12, the potentials of the word lines WL may be lowered gradually or stepwise between the fifth time T5 and the sixth time T6.

At the sixth time T6, the word lines WL may be discharged. For example, the ground voltage GND may be applied to the word lines WL.

At the seventh time T7, the drain select lines DSL coupled to the first sub-blocks 1SB may be discharged.

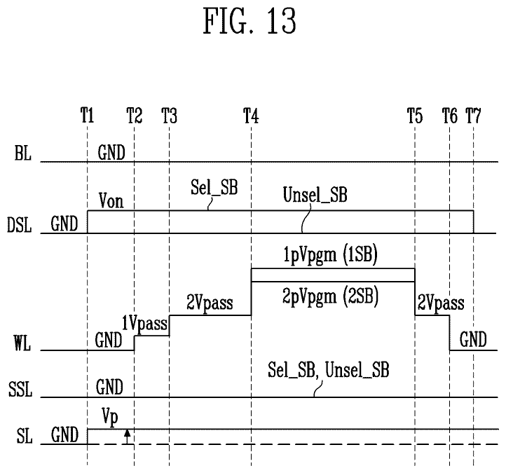

FIG. 13 is a diagram for describing a pre-program operation according to a third embodiment of the present disclosure.

Referring to FIG. 13, at the first time T1, when the pre-program operation starts, the turn-on voltage Von may be applied to the drain select lines DSL coupled to the selected sub-blocks Sel_SB, and the ground voltage GND may be applied to the drain select lines DSL coupled to the unselected sub-blocks Unsel_SB. When the selected sub-blocks Sel_SB are the first sub-blocks 1SB shown in FIGS. 7 and 8, the unselected sub-blocks Unsel_SB are the second sub-blocks 2SB shown in FIGS. 7 and 8. When the selected sub-blocks Sel_SB are the second sub-blocks 2SB, the unselected sub-blocks Unsel_SB are the first sub-blocks 1SB.

The turn-on voltage Von may be applied to the drain select lines DSL coupled to the selected sub-blocks Sel_SB, and the ground voltage GND may be applied to the drain select lines DSL coupled to the unselected sub-blocks Unsel_SB. The turn-on voltage Von applied to the drain select lines DSL coupled to the selected sub-blocks Sel_SB may be set to a positive voltage for turning on the drain select transistors. The ground voltage GND applied to the drain select lines DSL coupled to the unselected sub-blocks Unsel_SB is a voltage for turning off the drain select transistors included in the unselected sub-blocks Unsel_SB. The ground voltage GND may be applied to the source select lines SSL coupled to the selected sub-blocks Sel_SB and the unselected sub-blocks Unsel_SB.

The ground voltage GND may be applied to the bit lines BL. Because the drain select transistors of the selected sub-blocks Sel_SB are turned on and the source select transistors are turned off, the channels of the plugs included in the selected sub-blocks Sel_SB may be electrically coupled to the bit lines BL. Thus, the potentials of the channels of the selected sub-blocks Sel_SB may be lowered to the ground voltage GND level. Because the drain select transistors and the source select transistors of the unselected sub-blocks Unsel_SB are turned off, the channels of the plugs included in the unselected sub-blocks Unsel_SB are in a floating state.

A positive voltage Vp higher than the ground voltage GND may be applied to the source line SL. In this manner, the threshold voltages of the memory cells included in the unselected sub-blocks Unsel_SB may more effectively resist or be prevented from increasing during the pre-program operation of the memory cells included in the selected sub-blocks Sel_SB. At the first time T1, the ground voltage GND may be applied to the word lines WL.

At the second time T2, the first pass voltage 1Vpass higher than the ground voltage GND may be applied to the word lines WL. The first pass voltage 1Vpass may be applied to all word lines WL to turn on all memory cells included in the selected memory block.

At the third time T3, the second pass voltage 2Vpass which is higher than the first pass voltage 1Vpass may be applied to the word lines WL. The second pass voltage 2Vpass may be applied to the word lines WL to gradually increase the potentials of the word lines WL before the first or second pre-program voltage 1pVpgm or 2pVpgm is applied to the word lines WL.

At the fourth time T4, the first or second pre-program voltage 1pVpgm or 2pVpgm may be applied to the word lines WL. For example, when the first sub-blocks 1SB are the selected sub-blocks Sel_SB, the first pre-program voltage 1pVpgm may be applied to the word lines WL. When the second sub-blocks 2SB are the selected sub-blocks Sel_SB, the second pre-program voltage 2pVpgm may be applied to the word lines WL.

Because the potentials of the channels of the selected sub-blocks Sel_SB have the level of the negative voltage Vn, the threshold voltages of the memory cells included in the selected sub-blocks Sel_SB may be increased by the first or second pre-program voltage 1pVpgm or 2pVpgm. Because the channels of the unselected sub-blocks Unsel_SB are in a floating state, the channels thereof may be boosted due to the potentials of the word lines WL. Thus, the memory cells included in the unselected sub-blocks Unsel_SB may remain erased. The threshold voltages of the memory cells included in the first sub-blocks 1SB may increase from the fourth time T4 to the fifth time T5.

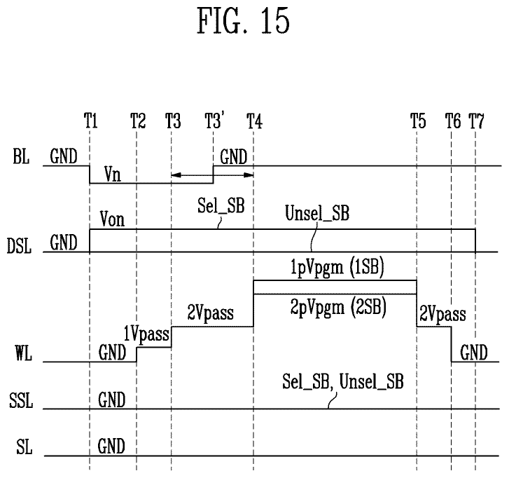

At the fifth time T5, the potentials of the word lines WL may be lowered gradually. For example, the second pass voltage 2Vpass, which is lower than the first or second pre-program voltage 1pVpgm or 2pVpgm, may be applied to the word lines WL. Though not shown in FIG. 15, the potentials of the word lines WL may be lowered gradually or stepwise between the fifth time T5 and the sixth time T6.

At the sixth time T6, the word lines WL may be discharged. For example, the ground voltage GND may be applied to the word lines WL.

At the seventh time T7, the drain select lines DSL coupled to the first sub-blocks 1SB may be discharged.

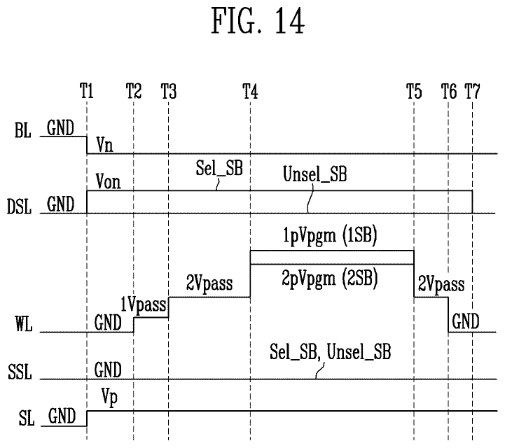

FIG. 14 is a diagram for describing a pre-program operation according to a fourth embodiment of the present disclosure.

Referring to FIG. 14, at the first time T1, when the pre-program operation starts, the turn-on voltage Von may be applied to the drain select lines DSL coupled to the selected sub-blocks Sel_SB, and the ground voltage GND may be applied to the drain select lines DSL coupled to the unselected sub-blocks Unsel_SB. When the selected sub-blocks Sel_SB are the first sub-blocks 1SB shown in FIGS. 7 and 8, the unselected sub-blocks Unsel_SB are the second sub-blocks 2SB shown in FIGS. 7 and 8. When the selected sub-blocks Sel_SB are the second sub-blocks 2SB, the unselected sub-blocks Unsel_SB are the first sub-blocks 1SB.

The turn-on voltage Von may be applied to the drain select lines DSL coupled to the selected sub-blocks Sel_SB, and the ground voltage GND may be applied to the drain select lines DSL coupled to the unselected sub-blocks Unsel_SB. The turn-on voltage Von applied to the drain select lines DSL coupled to the selected sub-blocks Sel_SB may be set to a positive voltage for turning on the drain select transistors. The ground voltage GND applied to the drain select lines DSL coupled to the unselected sub-blocks Unsel_SB is a voltage for turning off the drain select transistors included in the unselected sub-blocks Unsel_SB. The ground voltage GND may be applied to the source select lines SSL coupled to the selected sub-blocks Sel_SB and the unselected sub-blocks Unsel_SB.

The negative voltage Vn lower than the ground voltage GND may be applied to the bit lines BL. As the potentials of the bit lines BL decrease, the threshold voltages of the memory cells included in the selected sub-blocks Sel_SB may increase more rapidly, so that the time taken for the pre-program operation may be shortened. Because the drain select transistors of the selected sub-blocks Sel_SB are turned on and the source select transistors are turned off, the channels of the plugs included in the selected sub-blocks Sel_SB may be electrically coupled to the bit lines BL. Thus, the potentials of the channels of the selected sub-blocks Sel_SB may be lowered to the negative voltage Vn level. Because the drain select transistors and the source select transistors of the unselected sub-blocks Unsel_SB are turned off, the channels of the plugs included in the unselected sub-blocks Unsel_SB are in a floating state.

The positive voltage Vp higher than the ground voltage GND may be applied to the source line SL. In this manner, the threshold voltages of the memory cells included in the unselected sub-blocks Unsel_SB may more effectively resist or be prevented from increasing during the pre-program operation of the memory cells included in the selected sub-blocks Sel_SB. At the first time T1, the ground voltage GND may be applied to the word lines WL.

At the second time T2, the first pass voltage 1Vpass higher than the ground voltage GND may be applied to the word lines WL. The first pass voltage 1Vpass may be applied to all word lines WL to turn on all memory cells included in the selected memory block.

At the third time T3, the second pass voltage 2Vpass which is higher than the first pass voltage 1Vpass may be applied to the word lines WL. The second pass voltage 2Vpass may be applied to the word lines WL to gradually increase the potentials of the word lines WL before the first or second pre-program voltage 1pVpgm or 2pVpgm is applied to the word lines WL.

At the fourth time T4, the first or second pre-program voltage 1pVpgm or 2pVpgm may be applied to the word lines WL. For example, when the first sub-blocks 1SB are the selected sub-blocks Sel_SB, the first pre-program voltage 1pVpgm may be applied to the word lines WL. When the second sub-blocks 2SB are the selected sub-blocks Sel_SB, the second pre-program voltage 2pVpgm may be applied to the word lines WL.

Because the potentials of the channels of the selected sub-blocks Sel_SB have the level of the negative voltage Vn, the threshold voltages of the memory cells included in the selected sub-blocks Sel_SB may be increased by the first or second pre-program voltage 1pVpgm or 2pVpgm. Because the channels of the unselected sub-blocks Unsel_SB are in a floating state, the channels thereof may be boosted due to the potentials of the word lines WL. Thus, the memory cells included in the unselected sub-blocks Unsel_SB may remain erased. The threshold voltages of the memory cells included in the first sub-blocks 1SB may increase from the fourth time T4 to the fifth time T5.

At the fifth time T5, the potentials of the word lines WL may be lowered gradually. For example, the second pass voltage 2Vpass, which is lower than the first or second pre-program voltage 1pVpgm or 2pVpgm, may be applied to the word lines WL. Though not shown in FIG. 14, the potentials of the word lines WL may be lowered gradually or stepwise between the fifth time T5 and the sixth time T6.

At the sixth time T6, the word lines WL may be discharged. For example, the ground voltage GND may be applied to the word lines WL.

At the seventh time T7, the drain select lines DSL coupled to the first sub-blocks 1SB may be discharged.

FIG. 15 is a diagram for describing a pre-program operation according to a fifth embodiment of the present disclosure.

Referring to FIG. 15, at the first time T1, when the pre-program operation starts, the turn-on voltage Von may be applied to the drain select lines DSL coupled to the selected sub-blocks Sel_SB, and the ground voltage GND may be applied to the drain select lines DSL coupled to the unselected sub-blocks Unsel_SB. When the selected sub-blocks Sel_SB are the first sub-blocks 1SB shown in FIGS. 7 and 8, the unselected sub-blocks Unsel_SB are the second sub-blocks 2SB shown in FIGS. 7 and 8. When the selected sub-blocks Sel_SB are the second sub-blocks 2SB, the unselected sub-blocks Unsel_SB are the first sub-blocks 1SB.

The turn-on voltage Von may be applied to the drain select lines DSL coupled to the selected sub-blocks Sel_SB, and the ground voltage GND may be applied to the drain select lines DSL coupled to the unselected sub-blocks Unsel_SB. The turn-on voltage Von applied to the drain select lines DSL coupled to the selected sub-blocks Sel_SB may be set to a positive voltage for turning on the drain select transistors. The ground voltage GND applied to the drain select lines DSL coupled to the unselected sub-blocks Unsel_SB is a voltage for turning off the drain select transistors included in the unselected sub-blocks Unsel_SB. The ground voltage GND may be applied to the source select lines SSL coupled to the selected sub-blocks Sel_SB and the unselected sub-blocks Unsel_SB.

The negative voltage Vn lower than the ground voltage GND may be applied to the bit lines BL. As the potentials of the bit lines BL decrease, the threshold voltages of the memory cells included in the selected sub-blocks Sel_SB may increase more rapidly, so that the time taken for the pre-program operation may be shortened. Because the drain select transistors of the selected sub-blocks Sel_SB are turned on and the source select transistors are turned off, the channels of the plugs included in the selected sub-blocks Sel_SB may be electrically coupled to the bit lines BL. Thus, the potentials of the channels of the selected sub-blocks Sel_SB may be lowered to the negative voltage Vn level. Because the drain select transistors and the source select transistors of the unselected sub-blocks Unsel_SB are turned off, the channels of the plugs included in the unselected sub-blocks Unsel_SB are in a floating state.

The ground voltage GND may be applied to the source line SL. At the first time T1, the ground voltage GND may be applied to the word lines WL.

At the second time T2, the first pass voltage 1Vpass higher than the ground voltage GND may be applied to the word lines WL. The first pass voltage 1Vpass may be applied to all word lines WL to turn on all memory cells included in the selected memory block.

At the third time T3, the second pass voltage 2Vpass which is higher than the first pass voltage 1Vpass may be applied to the word lines WL. The second pass voltage 2Vpass may be applied to the word lines WL to gradually increase the potentials of the word lines WL before the first or second pre-program voltage 1pVpgm or 2pVpgm is applied to the word lines WL. The potential of the bit lines BL may be raised to the ground voltage GND level between the third time T3 and the fourth time T4. A third time T3′ at which the potential of the bit lines BL is raised from the negative voltage Vn level to the ground voltage GND level may occur between the third time T3 and the fourth time T4.

At the fourth time T4, the first or second pre-program voltage 1pVpgm or 2pVpgm may be applied to the word lines WL. For example, when the first sub-blocks 1SB are the selected sub-blocks Sel_SB, the first pre-program voltage 1pVpgm may be applied to the word lines WL. When the second sub-blocks 2SB are the selected sub-blocks Sel_SB, the second pre-program voltage 2pVpgm may be applied to the word lines WL.

Because the potentials of the channels of the selected sub-blocks Sel_SB have the level of the negative voltage Vn, the threshold voltages of the memory cells included in the selected sub-blocks Sel_SB may be increased by the first or second pre-program voltages 1pVpgm or 2pVpgm. Because the channels of the unselected sub-blocks Unsel_SB are in a floating state, the channels thereof may be boosted due to the potentials of the word lines WL. Thus, the memory cells included in the unselected sub-blocks Unsel_SB may remain erased. The threshold voltages of the memory cells included in the first sub-blocks 1SB may increase from the fourth time T4 to the fifth time T5.

At the fifth time T5, the potentials of the word lines WL may be lowered gradually. For example, the second pass voltage 2Vpass, which is lower than the first or second pre-program voltage 1pVpgm or 2pVpgm, may be applied to the word lines WL. Though not shown in FIG. 15, the potentials of the word lines WL may be lowered gradually or stepwise between the fifth time T5 and the sixth time T6.

At the sixth time T6, the word lines WL may be discharged. For example, the ground voltage GND may be applied to the word lines WL.

At the seventh time T7, the drain select lines DSL coupled to the first sub-blocks 1SB may be discharged.

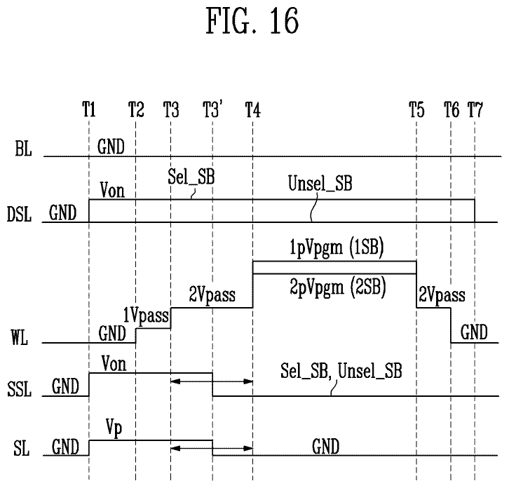

FIG. 16 is a diagram for describing a pre-program operation according to a sixth embodiment of the present disclosure.

Referring to FIG. 16, at the first time T1, when the pre-program operation starts, the turn-on voltage Von may be applied to the drain select lines DSL coupled to the selected sub-blocks Sel_SB, and the ground voltage GND may be applied to the drain select lines DSL coupled to the unselected sub-blocks Unsel_SB. When the selected sub-blocks Sel_SB are the first sub-blocks 1SB shown in FIGS. 7 and 8, the unselected sub-blocks Unsel_SB are the second sub-blocks 2SB shown in FIGS. 7 and 8. When the selected sub-blocks Sel_SB are the second sub-blocks 2SB, the unselected sub-blocks Unsel_SB are the first sub-blocks 1SB.

The turn-on voltage Von may be applied to the drain select lines DSL coupled to the selected sub-blocks Sel_SB, and the ground voltage GND may be applied to the drain select lines DSL coupled to the unselected sub-blocks Unsel_SB. The turn-on voltage Von applied to the drain select lines DSL coupled to the selected sub-blocks Sel_SB may be set to a positive voltage for turning on the drain select transistors. The ground voltage GND applied to the drain select lines DSL coupled to the unselected sub-blocks Unsel_SB is a voltage for turning off the drain select transistors included in the unselected sub-blocks Unsel_SB. The positive voltage Vp higher than the ground voltage GND may be applied to the source select lines SSL coupled to the selected sub-blocks Sel_SB and the unselected sub-blocks Unsel_SB.

The ground voltage GND may be applied to the bit lines BL. Because the drain select transistors and the source select transistors of the selected sub-blocks Sel_SB are turned on, the channels of the plugs included in the selected sub-blocks Sel_SB may be electrically coupled to the bit lines BL and the source line SL. Because the drain select transistors of the unselected sub-blocks Unsel_SB are turned off and the source select transistors are turned on, the channels of the plugs included in the unselected sub-blocks Unsel_SB may be electrically coupled to the source line SL.

The positive voltage Vp higher than the ground voltage GND may be applied to the source line SL. In this manner, the threshold voltages of the memory cells included in the unselected sub-blocks Unsel_SB may more effectively resist or be prevented from increasing during the pre-program operation of the memory cells included in the selected sub-blocks Sel_SB. At the first time T1, the ground voltage GND may be applied to the word lines WL.

At the second time T2, the first pass voltage 1Vpass higher than the ground voltage GND may be applied to the word lines WL. The first pass voltage 1Vpass may be applied to all word lines WL to turn on all memory cells included in the selected memory block.

Because the drain select transistors and the source select transistors of the selected sub-blocks Sel_SB are turned on, the potentials of the channels of the plugs included in the selected sub-blocks Sel_SB may be maintained at a level lower than the positive voltage Vp. Because the drain select transistors of the unselected sub-blocks Unsel_SB are turned off and the source select transistors are turned on, the potentials of the channels of the plugs included in the unselected sub-blocks Unsel_SB may be increased by the positive voltage Vp applied to the source line SL.

At the third time T3, the second pass voltage 2Vpass which is higher than the first pass voltage 1Vpass may be applied to the word lines WL. The second pass voltage 2Vpass may be applied to the word lines WL to gradually increase the potentials of the word lines WL before the first or second pre-program voltage 1pVpgm or 2pVpgm is applied to the word lines WL. The turn-on voltage Von applied to the source select lines SSL and the positive voltage Vp applied to the source line SL may be lowered to the ground voltage GND level between the third time T3 and the fourth time T4. The third time T3′ at which the source select lines SSL and the source line SL are discharged may be changed between the third time T3 and the fourth time T4.

At the fourth time T4, the first or second pre-program voltage 1pVpgm or 2pVpgm may be applied to the word lines WL. For example, when the first sub-blocks 1SB are the selected sub-blocks Sel_SB, the first pre-program voltage 1pVpgm may be applied to the word lines WL. When the second sub-blocks 2SB are the selected sub-blocks Sel_SB, the second pre-program voltage 2pVpgm may be applied to the word lines WL.

Because the potentials of the channels of the selected sub-blocks Sel_SB have the level of the negative voltage Vn, the threshold voltages of the memory cells included in the selected sub-blocks Sel_SB may be increased by the first or second pre-program voltages 1pVpgm or 2pVpgm. Because the channels of the unselected sub-blocks Unsel_SB are in a floating state, the channels thereof may be boosted due to the potentials of the word lines WL. Thus, the memory cells included in the unselected sub-blocks Unsel_SB may remain erased. The threshold voltages of the memory cells included in the first sub-blocks 1SB may increase from the fourth time T4 to the fifth time T5.

At the fifth time T5, the potentials of the word lines WL may be lowered gradually. For example, the second pass voltage 2Vpass, which is lower than the first or second pre-program voltage 1pVpgm or 2pVpgm, may be applied to the word lines WL. Though not shown in FIG. 16, the potentials of the word lines WL may be lowered gradually or stepwise between the fifth time T5 and the sixth time T6.

At the sixth time T6, the word lines WL may be discharged. For example, the ground voltage GND may be applied to the word lines WL.

At the seventh time T7, the drain select lines DSL coupled to the first sub-blocks 1SB may be discharged.

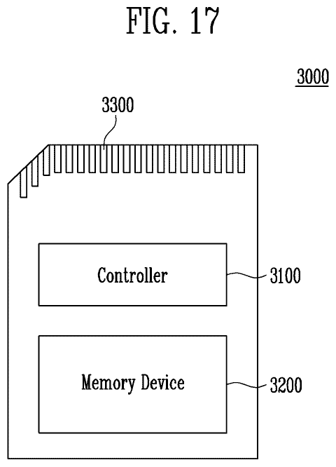

FIG. 17 is a diagram illustrating a memory card system 3000 to which a memory device according to an embodiment of the present disclosure is applied.

Referring to FIG. 17, the memory card system 3000 may include a controller 3100, a memory device 3200, and a connector 3300.

The controller 3100 may be coupled to the memory device 3200. For an embodiment, the controller 3100 may represent the controller 200 of FIG. 1 or the control circuit of FIG. 2. The controller 3100 may be configured to access the memory device 3200. For example, the controller 3100 may control a program operation, a read operation, an erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components, such as Random-Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols, such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described various communication protocols.

The memory device 3200 may include a plurality of memory cells and may be configured in the same manner as the memory device 100 shown in FIG. 2. For example, the memory device 3200 may perform a pre-program operation prior to an erase operation. During a pre-program operation, the memory device 3200 may adjust a level of a pre-program voltage applied to word lines according to selected sub-blocks included in a selected memory block. The memory device 3200 may adjust a voltage applied to at least one of a source line, a bit line, a drain select line, and a source select line in addition to a program voltage.

To reduce the time required for a program operation and mitigate or prevent disturbance, the channel precharge time may be adjusted according to sizes of memory cells included in a selected page during the program operation of the selected page of the selected memory block.

The controller 3100 and the memory device 3200 may be integrated into a single semiconductor device to constitute a memory card. For example, the controller 3100 and the memory device 3200 may constitute a memory card, such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro, or eMMC), an SD card (SD, miniSD, microSD, or SDHC), and a Universal Flash Storage (UFS).

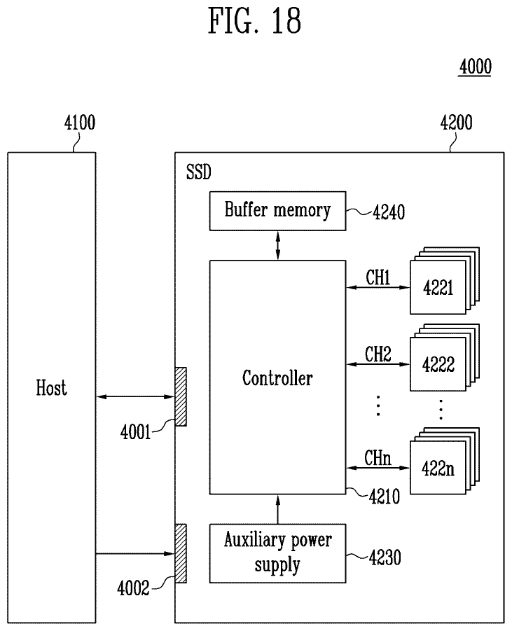

FIG. 18 is a diagram illustrating a solid-state drive (SSD) system 4000 to which a memory device according to an embodiment of the present disclosure is applied.

Referring to FIG. 18, the SSD system 4000 may include a host 4100 and an SSD 4200. The SSD 4200 may exchange signals with the host 4100 through a signal connector 4001, and it may receive power through a power connector 4002. The SSD 4200 may include a controller 4210, a plurality of memory devices 4221 to 422n, an auxiliary power supply 4230, and buffer memory 4240.

The controller 4210 may control the plurality of memory devices 4221 to 422n in response to signals received from the host 4100. For example, the signals may be based on an interface between the host 4100 and the SSD 4200. For example, the signals may be defined by at least one interface, such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), WI-FI, Bluetooth, and NVMe interfaces. For an embodiment, the controller 4210 may represent the controller 200 of FIG. 1 or the control circuit of FIG. 2.

The plurality of memory devices 4221 to 422n may include a plurality of memory cells configured to store data. Each of the plurality of memory devices 4221 to 422n may be configured in the same manner as the memory device 100 shown in FIG. 1. The plurality of memory devices 4221 to 422n may communicate with the controller 4210 through channels CH1 to CHn.

The auxiliary power supply 4230 may be coupled to the host 4100 through a power connector 4002. The auxiliary power supply 4230 may receive power input from the host 4100 and charge the power. When the supply of power from the host 4100 is not smooth, the auxiliary power supply 4230 may provide power to the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 may serve as buffer memory of the SSD 4200. For example, the buffer memory 4240 may temporarily store data received from the host 4100 or data received from the plurality of memory devices 4221 to 422n, or it may temporarily store metadata (e.g., mapping tables) of the memory devices 4221 to 422n. The buffer memory 4240 may include volatile memory, such as DRAM, SDRAM, DDR SDRAM, and LPDDR SDRAM, or non-volatile memory, such as FRAM, ReRAM, STT-MRAM, and PRAM.

According to the present disclosure, a phenomenon in which threshold voltages of memory cells are excessively lowered during an erase operation may be mitigated or prevented, and a time taken for a program operation may be shortened.

It will be apparent to those skilled in the art that various modifications can be made to the embodiments described herein without departing from the spirit or scope of the present teachings. Thus, it is intended that the present teachings cover all such modifications provided they come within the scope of the appended claims and their equivalents.

What is claimed is:

1. A memory device comprising:
a memory block including first sub-blocks and second sub-blocks located between a source line and bit lines;
a peripheral circuit configured to perform an erase operation of the memory block and pre-program operations of the first sub-blocks and then the second sub-blocks sequentially before the erase operation; and
a control circuit configured to control the peripheral circuit,
wherein each of the first and second sub-blocks includes first select transistors, memory cells, and second select transistors arranged between the source line and the bit lines, and
wherein the control circuit is configured to control the peripheral circuit to apply a first pre-program voltage to word lines coupled to the memory cells during the pre-program operation of the first sub-blocks, and to apply a second pre-program voltage lower than the first pre-program voltage to the word lines during the pre-program operation of the second sub-blocks.

2. The memory device of claim 1, wherein the second sub-blocks are located between the first sub-blocks.

3. The memory device of claim 1, wherein the control circuit is configured to control the peripheral circuit so that potentials of the word lines increase gradually before the first or second pre-program voltage is applied to the word lines.

4. The memory device of claim 3, wherein the control circuit is configured to control the peripheral circuit so that pass voltages lower than the first and second pre-program voltages are gradually applied to the word lines before the first or second pre-program voltage is applied to the word lines.

5. The memory device of claim 1, wherein the control circuit is configured to control the peripheral circuit so that among the second select transistors, select transistors included in the first sub-blocks are turned on and select transistors included in the second sub-blocks are turned off when the pre-program operation is performed on the first sub-blocks.

6. The memory device of claim 1, wherein the control circuit is configured to control the peripheral circuit so that among the second select transistors, select transistors included in the second sub-blocks are turned on and select transistors included in the first sub-blocks are turned off when the pre-program operation is performed on the second sub-blocks.

7. The memory device of claim 1, wherein the control circuit is configured to control the peripheral circuit to apply a ground voltage to a first select line coupled to the first select transistors.

8. The memory device of claim 1, wherein the control circuit is configured to control the peripheral circuit to apply a positive voltage higher than a ground voltage to a first select line coupled to the first select transistors.

9. The memory device of claim 1, wherein the control circuit is configured to control the peripheral circuit to apply a ground voltage to the bit lines.

10. The memory device of claim 1, wherein the control circuit is configured to control the peripheral circuit to apply a negative voltage lower than a ground voltage to the bit lines.

11. The memory device of claim 1, wherein the control circuit is configured to control the peripheral circuit to apply a ground voltage to the source line.

12. The memory device of claim 1, wherein the control circuit is configured to control the peripheral circuit to apply a positive voltage higher than a ground voltage to the source line.

13. The memory device of claim 12, wherein the control circuit is configured to control the peripheral circuit to discharge the source line, to which the positive voltage is applied, before the first or second pre-program voltage is applied to the word lines.

14. The memory device of claim 13, wherein the control circuit is configured to control the peripheral circuit to turn on the first select transistors when the positive voltage is applied to the source line.

15. A method of operating a memory device, the method comprising:
performing a first pre-program operation of first sub-blocks by applying a first pre-program voltage to word lines coupled to the first sub-blocks and second sub-blocks located between the first sub-blocks before an erase operation of a memory block including the first sub-blocks and the second sub-blocks; and
performing a second pre-program operation of the second sub-blocks by applying a second pre-program voltage lower than the first pre-program voltage to the word lines.

16. The method of claim 15, wherein potentials of the word lines are gradually increased to the first or second pre-program voltage before the first or second pre-program voltage, respectively, is applied to the word lines.

17. The method of claim 15, wherein a ground voltage is applied to bit lines coupled to the memory block when the first or second pre-program operation is performed.

18. The method of claim 15, wherein a negative voltage lower than a ground voltage is applied to bit lines coupled to the memory block when the first or second pre-program operation is performed.

19. The method of claim 15, wherein a ground voltage is applied to a source line coupled to the memory block when the first or second pre-program operation is performed.

20. The method of claim 15, wherein a positive voltage higher than a ground voltage is applied to a source line coupled to the memory block when the first or second pre-program operation is performed.

21. The method of claim 20, wherein the source line to which the positive voltage is applied is discharged before the first or second pre-program voltage is applied to the word lines.

22. The method of claim 20, wherein channels of plugs included in the first and second sub-blocks are electrically blocked from the source line when the positive voltage is applied to the source line.

23. The method of claim 15, wherein, when the first pre-program operation is performed:
channels of plugs included in the first sub-blocks are electrically coupled to bit lines, and
channels of plugs included in the second sub-blocks are electrically blocked from the bit lines.

24. The method of claim 15, wherein, when the second pre-program operation is performed:
channels of plugs included in the second sub-blocks are electrically coupled to bit lines, and
channels of plugs included in the first sub-blocks are electrically blocked from the bit lines.
